(19) United States
(12) Patent Application Publication
(10) Pub. No.: US 2024/0263801 A1
(43) Pub. Date: Aug. 8, 2024

(54) THERMAL TREATMENT APPARATUS AND THERMAL TREATMENT METHOD

(71) Applicant: Tokyo Electron Limited, Tokyo (JP)

(72) Inventors: Tatsuya KAWAJI, Koshi City (JP); Shinichiro YAMANAKA, Koshi City (JP); Kei MIYAZAKI, Koshi City (JP); Shinichi SAGARA, Koshi City (JP)

(21) Appl. No.: 18/421,407

(22) Filed: Jan. 24, 2024

(30) Foreign Application Priority Data
Feb. 6, 2023 (JP) 2023-015845
Nov. 14, 2023 (JP) 2023-193578

(51) Int. Cl. F24C 15/10; F24C 7/08; F24C 15/12; F24C 15/32

(52) U.S. Cl. CPC F24C 15/101; F24C 15/103; F24C 15/322; F24C 7/083; F24C 15/12

(57) ABSTRACT

A thermal treatment apparatus includes: a hot plate on which a substrate is mounted and which is configured to heat the substrate; an upper cover configured to cover a treatment space above the hot plate and form an opening being a carry-in/out port for the substrate to/from the treatment space; an exhauster provided at a position opposite to the opening across the hot plate in plan view and configured to exhaust gas from the treatment space; a shutter configured to cover a lower portion of the opening; and a gas flow guide provided at a position spaced apart from the shutter, wherein the gas flow guide divides gas flowing into the treatment space due to the exhaust of gas by the exhauster from an upper portion of the opening whose lower portion is covered with the shutter, into an upper side and a lower side.

### CROSS REFERENCE TO RELATED APPLICATIONS

This application is based upon and claims the benefit of priority of the prior Japanese Patent Application No. 2023-15845, filed in Japan on Feb. 6, 2023, and the prior Japanese Patent Application No. 2023-193578, filed in Japan on Nov. 14, 2023, the entire contents of which are incorporated herein by reference.

### TECHNICAL FIELD

This disclosure relates to a thermal treatment apparatus and a thermal treatment method.

### BACKGROUND

Japanese Laid-open Patent Publication No. 2016-201399 discloses a heating apparatus which mounts a substrate having a coating film formed thereon on a stage provided in a housing and heat-treats the substrate by a heating part. This heating apparatus includes: a delivery part which is provided in front of the stage in the housing and delivers the substrate to/from an external transfer mechanism; an exhaust port which exhausts gas from the housing to form a gas flow proceeding from the delivery part side to a region above the stage; and a carrier mechanism which carries the substrate between the delivery part and the stage. The heating apparatus further includes a gas flow blocking mechanism for blocking the gas flow flowing between the delivery part side and the stage side, at a position on the side closer to the delivery portion than the mounting region of the substrate on the stage when the carrier mechanism carries the substrate after the heat treatment from the stage to the delivery part side.

### SUMMARY

An aspect of this disclosure is a thermal treatment apparatus for performing a heat treatment on a substrate, the thermal treatment apparatus including: a hot plate on which the substrate is mounted and which is configured to heat the mounted substrate; an upper cover configured to cover a treatment space above the hot plate and form an opening being a carry-in/out port for the substrate to/from the treatment space; an exhauster provided at a position opposite to the opening across the hot plate in plan view and configured to exhaust gas from the treatment space; a shutter configured to be able to cover a lower portion of the opening; and a gas flow guide provided at a position spaced apart from the shutter, wherein the gas flow guide divides gas flowing into the treatment space due to the exhaust of gas by the exhauster from an upper portion of the opening whose lower portion is covered with the shutter, into an upper side and a lower side.

### BRIEF DESCRIPTION OF THE DRAWINGS

FIG. 1 is a transverse sectional view illustrating the outline of a configuration of a thermal treatment apparatus according to this embodiment.

FIG. 2 is a longitudinal sectional view illustrating the outline of the configuration of the thermal treatment apparatus according to this embodiment.

FIG. 3 is a partially enlarged view of FIG. 2.

FIG. 4 is a front view of a shutter.

FIG. 5 is an explanatory view of an attachment form of a gas flow guide.

FIG. 6 is a view schematically illustrating a simulation result of a gas flow near an opening formed by an upper cover in a thermal treatment apparatus in a comparative form.

FIG. 7 is a view schematically illustrating a simulation result of a gas flow near an opening formed by an upper cover in the thermal treatment apparatus in FIG. 1 and FIG. 2.

FIG. 8 is a view for explaining the operation and effect of a base wall and an exhaust port provided in the base wall.

FIG. 9 is a view explaining another example of the thermal treatment sequence.

FIG. 10 is a view explaining another example of an exhauster.

FIG. 11 is a view explaining another example of the exhauster.

FIG. 12 is a view explaining another example of a peripheral cover.

FIG. 13 is a view explaining an inclination processed portion of a peripheral cover in FIG. 12.

### DETAILED DESCRIPTION

In a manufacturing process of a semiconductor device or the like, a coating film such as a resist film is formed on a substrate such as a semiconductor wafer (hereinafter, referred to as a “wafer”).

In the case where the coating film is formed on the substrate, a heat treatment is performed on the substrate in order to adjust the degree of drying of the coating film. This heat treatment is usually performed in a thermal treatment apparatus having a hot plate on which the substrate is mounted and which heats the substrate.

In the thermal treatment apparatus, gas therein is exhausted during the heat treatment for the purpose of recovering a solvent vaporized from the coating film by the heating or the like. In an exhaust system in the thermal treatment apparatus, a discharge port for gas is provided above a peripheral portion of the hot plate, an exhaust port is provided above a central portion of the hot plate, and a gas flow flowing from the peripheral portion to the central portion of the hot plate is formed to exhaust gas. Besides, in another exhaust system, an exhauster which exhausts gas from a treatment space above the hot plate and a carry-in/out port for the substrate to/from the treatment space are provided at positions opposite to each other across the hot plate in plan view, and gas is exhausted to form a gas flow in a unidirectional flow flowing from the carry-in/out port to the exhauster. Although the result may vary depending on the film type, the latter system can dry the coating film uniformly within the plane of the substrate as compared with the former system. However, in the latter system, the drying of the coating film becomes excessive at a portion on the upstream side of the unidirectional flow on the substrate, so that when development or the like is performed thereafter, the coating film may unintentionally remain, namely, a residue may be produced. Note that in a method of suppressing the excessive drying at the portion on the upstream side of the unidirectional flow, the heating time of the substrate is shortened. However, in this method, the solidification of the coating film may be insufficient at a portion different from the portion on the upstream side of the unidirectional flow.

Hence, the technique according to this disclosure improves the in-plane uniformity of a heat treatment in the case of performing a heat treatment of drying a coating film formed on a substrate in a treatment space in a state where a gas flow formed by a carry-in/out port for the substrate and an exhauster opposite to each other across a hot plate in plan view is formed in the treatment space above the hot plate.

Hereinafter, a substrate treatment apparatus and a substrate treatment method according to this embodiment will be explained with reference to the drawings. Note that, in this description, components having substantially the same functional configurations are denoted by the same reference signs to omit duplicate explanations.

### Thermal Treatment Apparatus

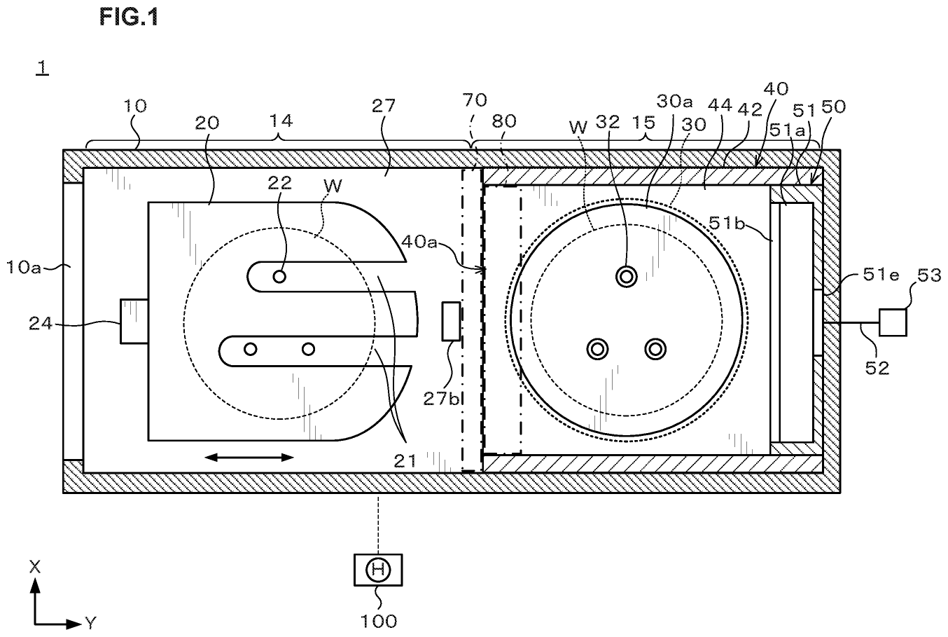

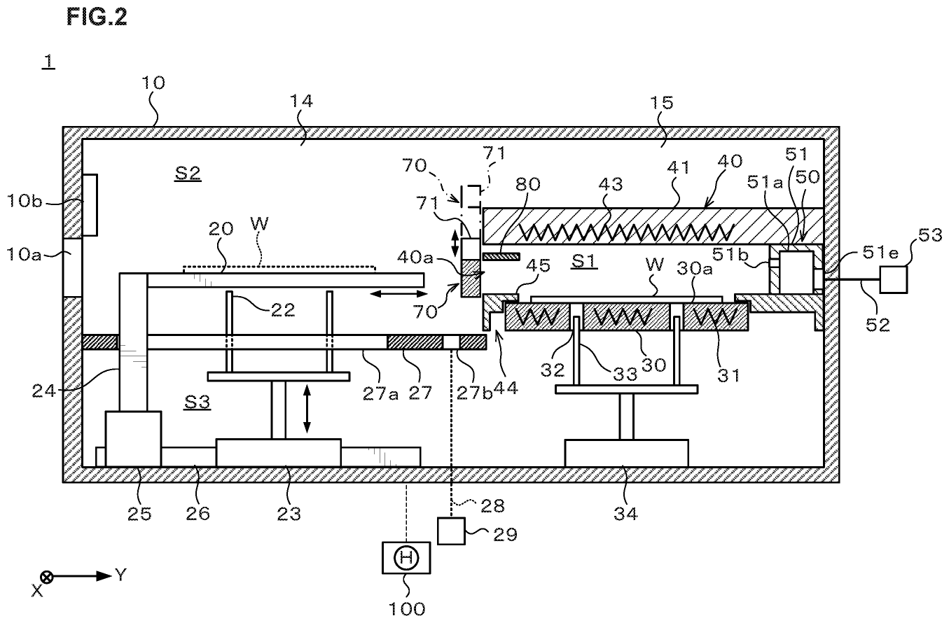

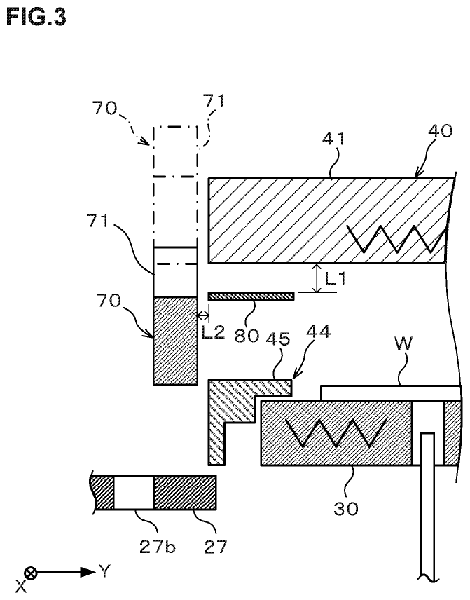

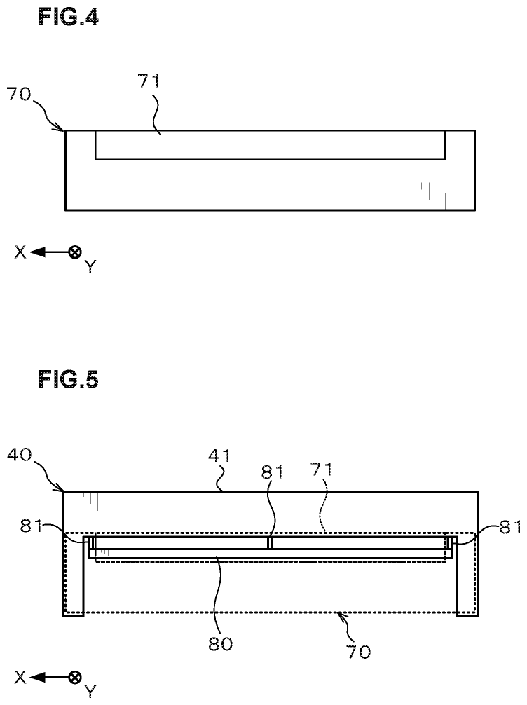

FIG. 1 and FIG. 2 are a transverse sectional view and a longitudinal sectional view illustrating the outline of a configuration of a thermal treatment apparatus according to this embodiment, respectively. FIG. 3 is a partially enlarged view of FIG. 2. FIG. 4 is a front view of a later-explained shutter. FIG. 5 is an explanatory view of an attachment form of a later-explained gas flow guide.

A thermal treatment apparatus 1 has a housing 10 whose inside is sealable as illustrated in FIG. 1 and FIG. 2. The housing 10 has, for example, a rectangular parallelepiped shape. At an upper portion of a side wall on one side of the housing 10, a carry-in/out port 10a for the wafer W as the substrate to/from the inside of the housing 10 is formed, and an opening and closing shutter 10b is provided at the carry-in/out port 10a.

Further, the housing 10 has a temperature regulation region 14 where the wafer W is cooled and thereby temperature-regulated, on the carry-in/out port 10a side, namely, a front side (Y-direction negative side in the drawing), and has a heating region 15 where the wafer W is heated, on a deep side (Y-direction positive side in the drawing).

A cooling plate 20 on which the wafer W is mounted and which cools the mounted wafer W to temperature-regulate it is provided in the temperature regulation region 14, and a hot plate 30 on which the wafer W is mounted and which heats the mounted wafer W is provided in the heating region 15.

The hot plate 30 has a thick almost disk shape. The hot plate 30 has a horizontal upper surface 30a, and the upper surface 30a is provided with, for example, a not-illustrated suction port which sucks the wafer W, so that the wafer W can be suction-held on the hot plate 30 by suction through the suction port.

In the hot plate 30, a heater 31 which heats the hot plate 30 is provided as illustrated in FIG. 2. As the heater 31, for example, a resistance heating type is used. The hot plate 30 can be regulated at a predetermined temperature by controlling the supply amount of power to the heater 31 by a later-explained controller 100.

Further, the hot plate 30 is supported in the housing 10 by a support member (not illustrated).

The hot plate 30 is provided with a plurality of through holes 32 penetrating it in the vertical direction. In the through holes 32, raising and lowering pins 33 are provided as raising and lowering members which raise and lower the wafer W with respect to the hot plate 30. The raising and lowering pins 33 are connected to a raising and lowering mechanism 34, and are configured to be able to rise and lower by the raising and lowering mechanism 34. The raising and lowering mechanism 34 has a driving source (not illustrated) such as a motor which generates a driving force for raising and lowering the raising and lowering pins 33. The raising and lowering pins 33 can pass through the through holes 32 and project from the upper surface 30a of the hot plate 30, and can rise and lower while supporting the wafer W.

The raising and lowering mechanism 34 is controlled by the later-explained controller 100.

Further, an upper cover 40 is provided in the heating region 15. The upper cover 40 covers a treatment space S1 above the hot plate 30 and forms an opening 40a being a carry-in/out port for the wafer W to/from the treatment space S1.

The upper cover 40 has a ceiling part 41 and a side wall part 42 as illustrated in FIG. 1 and FIG. 2.

The ceiling part 41 is provided in a manner to face the hot plate 30 as illustrated in FIG. 2 and covers an upper portion of the treatment space S1. Inside the ceiling part 41, a heater 43 which heats the ceiling part 41 is provided separately from (the heater 31 of) the hot plate 30. As the heater 43, for example, a resistance heating type is used. The ceiling part 41 is regulated to a temperature higher than room temperature and lower than that of the hot plate 30 by the heater 43 under the control of the later-explained controller 100.

The side wall part 42 has an upper end connected to the ceiling part 41 and covers a lateral side of the treatment space S1 as illustrated in FIG. 2.

Further, in the heating region 15, a peripheral cover 44 is provided in a manner to surround the periphery of the lateral side of the hot plate 30 as illustrated in FIG. 2 and FIG. 3. The peripheral cover 44 has, for example, an annular part 45 at the upper end. The annular part 45 is provided in a manner to cover a gap at the lateral side of the hot plate 30 from above and extend to above the peripheral portion of the hot plate 30. Specifically, the annular part 45 is formed in an annular shape (specifically, a circular shape) in a manner to cover the gap between an inner peripheral wall of the peripheral cover 44 facing the side surface of the hot plate 30 and the side surface of the hot plate 30, from above over the entire peripheral direction of the hot plate 30, and its inner end is located above the peripheral portion of the hot plate 30.

The peripheral cover 44 is fixed to the peripheral portion of the hot plate 30, for example, at the annular part 45. In one embodiment, the annular part 45 of the peripheral cover 44 in a state where it is fixed as above has a gap with respect to the hot plate 30 except for a portion fixed to the hot plate 30.

Besides, the position of the upper surface of the peripheral cover 44 (specifically, the upper surface of the annular part 45) is higher than the position of the front surface of the wafer W mounted on the hot plate 30.

Further, in the heating region 15, an exhauster 50 which exhausts gas from the treatment space S1 is provided as illustrated in FIG. 1 and FIG. 2. The exhauster 50 has a forming member 51 which forms an exhaust flow path 51a communicating with the treatment space S1. The exhaust flow path 51a includes an exhaust port 51b opening to the treatment space S1. Specifically, the exhaust flow path 51a has the exhaust port 51b on its exhaust upstream side end. Further, the exhaust flow path 51a is connected to an exhaust mechanism 53 via an exhaust pipe 52. Specifically, an outlet port 51e provided at an exhaust downstream side end of the exhaust flow path 51a is connected to the exhaust mechanism 53 via the exhaust pipe 52. The exhaust mechanism 53 has an exhaust pump (not illustrated) which exhausts gas and a regulating valve (not illustrated) which regulates an exhaust rate.

The exhaust mechanism 53 is controlled by the later-explained controller 100.

Further, in the exhaust flow path 51a, the exhaust port 51b is larger than the outlet port 51e in length in a predetermined direction being a direction in which the opening 40a extends and which crosses a vertical direction, namely, an X-direction in the drawing.

The above exhauster 50 (specifically, the exhaust port 51b) is provided at a position opposite to the above opening 40a across the hot plate 30 in plan view. In other words, the opening 40a is provided at a position on the front side of the hot plate 30 (on the Y-direction negative side in the drawing), whereas the exhauster 50 (specifically, the exhaust port 51b) is provided on the deep side of the hot plate 30 (on the Y-direction positive side in the drawing).

The exhaust port 51b of the exhauster 50 has a width in a direction (X-direction in the drawing) intersecting, in plan view, with a direction (Y-direction) in which the temperature regulation region 14 and the heating region 15 are arranged side by side), for example, as illustrated in FIG. 1. The width of the exhaust port 51b in the intersecting direction is, for example, substantially the same as the diameter of the wafer W.

Further, the exhaust port 51b is provided at a position above the hot plate 30 (specifically, above the wafer W on the hot plate 30) as illustrated in FIG. 2.

The cooling plate 20 has a flat-plate shape in an almost square and has an end surface on the hot plate 30 side curved in an arc shape as illustrated in FIG. 1. Two cutouts 21 along the depth direction (Y-direction in the drawing) are formed in the cooling plate 20 and can prevent the cooling plate 20 from interfering with the raising and lowering pins 33 and raising and lowering pins 22 provided for the cooling plate 20. The raising and lowering pins 22 are members which raise and lower the wafer W with respect to the cooling plate 20, and are connected to a raising and lowering mechanism 23 as illustrated in FIG. 2 and configured to be able to rise and lower by the raising and lowering mechanism 23. The raising and lowering mechanism 23 has a driving source (not illustrated) such as a motor which generates a driving force for raising and lowering the raising and lowering pins 22. The raising and lowering pins 22 can project from the upper surface of the cooling plate 20 via the cutouts 21, and can rise and lower while supporting the wafer W.

The raising and lowering mechanism 23 is controlled by the later-explained controller 100.

Further, the cooling plate 20 has, for example, a temperature regulating member (not illustrated) such as a Peltier element built therein.

The cooling plate 20 is supported by a support arm 24. The support arm 24 is attached to a rail 26 extending in the depth direction (Y-direction in the drawing) via a drive mechanism 25 at a lower portion in the housing 10. The rail 26 extends from below the cooling plate 20 to the vicinity below the opening 40a. By the above drive mechanism 25, the cooling plate 20 can move along the rail 26 to above the hot plate 30. The drive mechanism 25 has a driving source (not illustrated) such as a motor which generates a driving force for moving the cooling plate 20, and is controlled by the later-explained controller 100.

Further, below the cooling plate 20, a base wall 27 is provided. The base wall 27 covers, from below, another space S2 on the side opposite to the treatment space S1 across a later-explained shutter 70. In other words, the base wall 27 is a member which partitions the other space S2 on the upper side and a space S3 on the lower side at a portion on the front side (Y-direction negative side) in the housing 10.

The base wall 27 is provided with a slit 27a which extends along the moving direction (Y-direction in the drawing) of the cooling plate 20 and through which the support arm 24 is inserted in order to avoid the interference with the support arm 24.

Further, the base wall 27 is provided with an exhaust port 27b which exhausts gas from the other space S2 from below the later-explained shutter 70. The exhaust port 27b is provided near the shutter 70 in top view, specifically, provided, for example, at a position which overlaps with the shutter 70 but does not overlap with a gap G between the shutter 70 and a later-explained gas flow guide 80 in top view. However, the exhaust port 27b may be provided at a position which overlaps with the gap G in top view.

The exhaust port 27b is connected, via an exhaust path 28, to an exhaust mechanism 29 having an exhaust pump (not illustrated) which exhausts gas, a regulating valve (not illustrated) which regulates an exhaust rate, and so on. The above exhaust mechanism 53 may also serve as the exhaust mechanism 29.

The purpose of exhausting gas from the other space S2 is, for example, removal of particles (namely, foreign substances) in the treatment space S1 and the like. The particles in the treatment space S1 may be produced during the movement of the support arm 24.

Further, in the housing 10, the shutter 70 is provided which is configured to be able to cover a lower portion of the opening 40a. The shutter 70 is a plate-shaped member and is provided, at its upper portion, with a notch 71 recessed downward in front view (Y-direction view in the drawing) as illustrated in FIG. 4. The provision of the notch 71 can prevent an upper portion of the opening 40a from being closed when the lower portion of the opening 40a is covered with the lower portion of the shutter 70.

Further, the shutter 70 is configured to be able to rise and lower by a raising and lowering mechanism (not illustrated). This raising and lowering mechanism has a driving source (not illustrated) such as a motor which generates a driving force for raising and lowering the shutter 70. The shutter 70 can rise and lower, by the raising and lowering mechanism, between a wafer carry position (position indicated by virtual lines in FIG. 2 and FIG. 3) and a treatment position (position indicated by solid lines in FIG. 2 and FIG. 3) below it. The wafer carry position is a position of the shutter 70 when the wafer W is carried-in/out to/from the treatment space S1 and is, for example, a position where the entire opening 40a is not covered with the shutter 70 but is opened. Besides, the treatment position is a position of the shutter 70 at the heat treatment of the wafer W by the hot plate 30 and is a position where the entire lower portion of the opening 40a is covered with the shutter 70.

The raising and lowering mechanism for the shutter 70 is controlled by the later-explained controller 100.

Note that in order to more surely prevent the shutter 70 from colliding with the upper cover 40, the peripheral cover 44, and the later-explained gas flow guide 80 during its raising and lowering, gaps are provided between them and the shutter 70.

In the thermal treatment apparatus 1, when exhaust of gas via the exhauster 50 is performed at the heat treatment of the wafer W by the hot plate 30, the atmosphere in the other space S2 is taken into the treatment space S1 via the upper portion of the opening 40a which is not covered with the shutter 70 at the treatment position, and flows toward the exhauster 50. In other words, in the thermal treatment apparatus 1, when exhaust of gas via the exhauster 50 is performed at the heat treatment of the wafer W by the hot plate 30, the gas in the other space S2 flows into the treatment space S1 via the notch 71 of the shutter 70 at the treatment position and the upper portion of the opening 40a, and flows toward the exhauster 50.

Further, in the housing 10, the gas flow guide 80 is provided at a position spaced apart from the shutter 70 in the treatment space S1. When the exhaust of gas via the exhauster 50 is performed, the gas flow guide 80 divides the gas flowing from the other space S2 into the treatment space S1 via the notch 71 of the shutter 70 at the treatment position and the upper portion of the opening 40a, into an upper side and a lower side.

As illustrated in FIG. 1, the gas flow guide 80 is provided along a predetermined direction being a direction in which the opening 40a extends and which crosses the vertical direction, namely, the X-direction in the drawing. More specifically, the gas flow guide 80 is provided horizontally and along the X-direction in the drawing.

Further, the gas flow guide 80 is provided, for example, at a height satisfying the following condition (A).
(A) As illustrated in FIG. 3, an interval L1 between the gas flow guide 80 and a ceiling surface being a surface on the treatment space S1 side and the lower side of the upper cover 40 (namely, a lower surface of the ceiling part 41) is larger than an interval L2 between the shutter 70 and the gas flow guide 80.

Further, a width (length in the Y-direction in the drawing) of the gas flow guide 80 is a width where an end on the hot plate 30 side (Y-direction positive side in the drawing) of the gas flow guide 80 does not overlap with the wafer W mounted on the hot plate 30 in top view. Further, a length of the gas flow guide 80 (specifically, a length in the X-direction in the drawing) is larger than, for example, the diameter of the hot plate 30.

A height of the gas flow guide 80 is, for example, the same as that of a lower end of the notch 71 of the shutter 70 at the treatment position.

Further, the gas flow guide 80 is attached, for example, to the ceiling surface of the upper cover 40 (namely, the lower surface of the ceiling part 41) as illustrated in FIG. 5. Specifically, the gas flow guide 80 is attached by being connected, for example, at its central portion and both end portions in the predetermined direction (X-direction in the drawing), to the lower surface of the ceiling part 41. The connection between the central portion and both the end portions in the predetermined direction (X-direction in the drawing) of the gas flow guide 80 and the lower surface of the ceiling part 41 is performed via metal members 81 of stainless steel or the like high in thermal conductivity. Further, the gas flow guide 80 may be connected to the lower surface of the ceiling part 41 via the metal members 81 also at portions between the central portion and both the end portions.

The metal members 81 at both the end portions in the predetermined direction (X-direction in the drawing) may be provided at positions outside the notch 71 of the shutter 70 in the predetermined direction. This can prevent the flow of the gas flowing into the treatment space S1 via the opening 40a from being disturbed by the metal members 81 at both the end portions.

In the above thermal treatment apparatus 1, the controller 100 is provided as illustrated in FIG. 1 and FIG. 2. The controller 100 processes computer-executable instructions which cause the thermal treatment apparatus 1 to execute various processes explained in this disclosure. The controller 100 can be configured to control components of the thermal treatment apparatus 1 so as to execute the various processes explained herein. In one embodiment, a part or all of the controller 100 may be included in the thermal treatment apparatus 1. The controller 100 may include a processor, a storage, and a communication interface. The controller 100 can be realized, for example, by the computer. The processor can be configured to read from the storage a program which provides a logic or routine making it possible to perform various control operations, and execute the read program to thereby perform the various control operations. This program may be stored in the storage in advance, or acquired via a medium when necessary. The acquired program is stored in the storage and read from the storage and executed by the processor. The medium may be various computer-readable storage media M or may be a communication line connected to the communication interface. The storage medium M may be a transitory one or a non-transitory one. The processor may be a CPU (Central Processing Unit). The storage may include a RAM (Random Access Memory), a ROM (Read Only Memory), an HDD (Hart Disk Drive), an SSD (Solid State Drive), or a combination of them. The communication interface may communicate with the thermal treatment apparatus 1 via a communication line such as a LAN (Local Area Network). A part or all of the controller 100 may be composed of a circuitry.

### Thermal Treatment Sequence

Next, an example of a thermal treatment sequence for the wafer W executed by the thermal treatment apparatus 1 will be explained. Note that the following processes are executed under the control of the controller 100 based on the program stored in the above storage (not illustrated). Further, it is assumed that the coating film of the resist solution has been formed on the wafer W being a treatment target. Note that, as the resist solution, for example, the one containing a solvent relatively high in boiling point such as N-methylpyrrolidone or γ-butyrolactone and a solute such as polyimide is used. Besides, the thickness of the coating film is, for example, 1 μm or more.

Further, the carry-in/out port 10a is brought into an open state by the opening and closing shutter 10b, and the wafer W held by a wafer carrier apparatus (not illustrated) outside the thermal treatment apparatus 1 is carried into the temperature regulation region 14 ivia the carry-in/out port 10a. Thereafter, the raising and lowering pins 22 are raised, whereby the wafer W is delivered to the raising and lowering pins 22.

Subsequently, the wafer carrier apparatus (not illustrated) is pulled out of the inside of the temperature regulation region 14, and the raising and lowering pins 22 are lowered, whereby the wafer W is delivered to the cooling plate 20. Further, the carry-in/out port 10a is brought into a closed state by the opening and closing shutter 10b, and then the exhaust of gas from the space S2 via the exhaust port 27b is started. Note that at this point in time, the position of the shutter 70 is the carry position, and the exhaust of gas from the space S2 via the exhauster 50 is not started.

Subsequently, the wafer W is carried into the treatment space S1. Specifically, the cooling plate 20 on which the wafer W is mounted is moved to above the hot plate 30 via the opening 40a which is not covered with the shutter 70 and is in the fully open state. Note that the temperature of the hot plate 30 has been raised to a predetermined temperature in advance.

Thereafter, the raising and lowering pins 33 are raised, whereby the wafer W is delivered to the raising and lowering pins 33, and then the cooling plate 20 is retreated from above the hot plate 30 to the temperature regulation region 14.

Next, the shutter 70 is lowered down to the treatment position, the lower portion of the opening 40a is covered with the shutter 70, and the exhaust of gas from the treatment space S1 by the exhauster 50 is started.

Upon completion of the lowering of the shutter 70, the raising and lowering pins 33 are lowered, whereby the wafer W is mounted on the hot plate 30, and the heating of the wafer W is started. While the wafer W is being heated by the hot plate 30, the exhaust of gas by the exhauster 50 is continued.

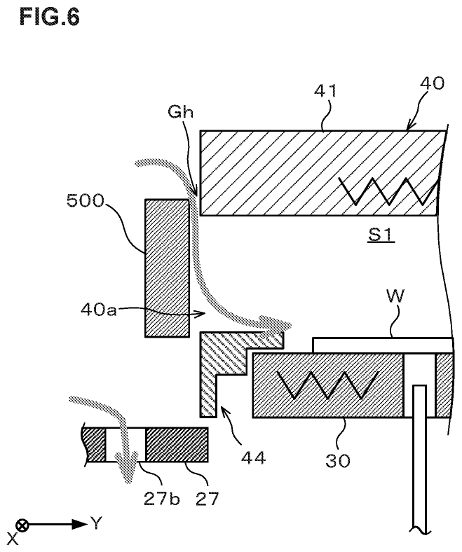

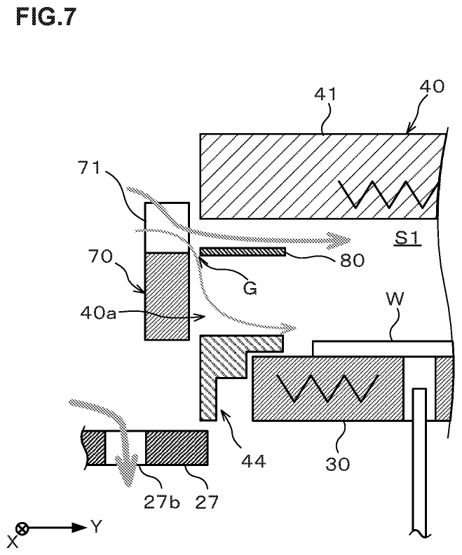

FIG. 6 and FIG. 7 are views schematically illustrating simulation results of gas flows near the opening 40a, respectively. FIG. 7 indicates the result when the exhaust of gas by the exhauster 50 was performed in a state where the shutter 70 was lowered down to the treatment position in the thermal treatment apparatus 1. On the other hand, FIG. 6 indicates the result, in a thermal treatment apparatus (hereinafter, referred to as a “thermal treatment apparatus in a comparative form”) having a shutter 500 with the gas flow guide 80 omitted from the thermal treatment apparatus 1 and without the notch 71, when the exhaust of gas by the exhauster 50 was performed in a state where the entire opening 40a was covered with the shutter 500. Note that in FIG. 6 and FIG. 7, the gas flows are indicated by gray arrows. Further, in FIG. 6 and FIG. 7, the strength of the gas flow is represented by the thickness of the gray arrow, in which the gas flow is stronger as the gray arrow is thicker.

In the thermal treatment apparatus in the comparative form, when the exhaust of gas by the exhauster 50 is performed in the state where the entire opening 40a is covered with the shutter 500 as illustrated in FIG. 6, the gas flows into a gap Gh between a front surface of the ceiling part 41 of the upper cover 40 and a rear surface of an upper portion of the shutter 500 from above the shutter 500, and flows into the treatment space S1 via the upper portion of the opening 40a. The gas flow flowing into the gap Gh is strong and proceeds downward from the gap Gh, and then proceeds along the upper surface of the peripheral cover 44 toward the wafer W on the hot plate 30. Therefore, the strong gas flow hits the peripheral portion on the opening 40a side of the wafer W on the hot plate 30. Accordingly, in the thermal treatment apparatus in the comparative form, the drying of the coating film may become excessive at the peripheral portion on the opening 40a side of the wafer W on the hot plate 30.

On the other hand, in the thermal treatment apparatus 1, when the exhaust of gas by the exhauster 50 is performed in the state where the shutter 70 is lowered down to the treatment position as illustrated in FIG. 7, the gas flowing into the treatment space S1 via the notch 71 of the shutter 70 and the upper portion of the opening 40a is divided by the gas flow guide 80 to form two gas flows near the opening 40a. The gas flow which flows between the ceiling part 41 of the upper cover 40 and the gas flow guide 80 and the gas flow which proceeds downward via the gap G between the front end of the gas flow guide 80 and the rear surface of the shutter 70 and then proceeds along the upper surface of the peripheral cover 44 toward the wafer W on the hot plate 30, are formed. In other words, in the thermal treatment apparatus 1, the gas flow flowing into the treatment space S1 via the upper portion of the opening 40a includes not only the gas flow which proceeds downward via the gap G and hits the wafer W on the hot plate 30 but also the gas flow which proceeds at the upper portion of the treatment space S1 along the ceiling part 41, unlike the thermal treatment apparatus in the comparative form. Therefore, the gas flow which proceeds downward via the gap G and hits the wafer W on the hot plate 30 is weak. Accordingly, in the thermal treatment apparatus 1, the drying of the coating film can be prevented from becoming excessive at the peripheral portion on the opening 40a side of the wafer W on the hot plate 30.

Further, the gas flow flows at the upper portion of the treatment space S1 in the thermal treatment apparatus 1, so that a volatile component at a position spaced upward from the wafer W is easily recovered even at a portion on the exhauster 50 side of the wafer W that is far away from the opening 40a. This makes it possible to prevent the concentration of a vaporized solvent from becoming high around the portion on the exhauster 50 side of the wafer W and the solvent from becoming difficult to vaporize from the coating film.

Note that in the case where the gas flow guide 80 is omitted from the thermal treatment apparatus 1, when the exhaust of gas by the exhauster 50 is performed in the state where the shutter 70 is lowered down to the treatment position, the gas flowing into the treatment space S1 via the notch 71 of the shutter 70 and the upper portion of the opening 40a forms a gas flow proceeding diagonally downward. In other words, the flowing gas forms a gas flow proceeding to the peripheral portion on the opening 40a side of the wafer W on the hot plate 30 without being divided by the gas flow guide 80. Therefore, the gas flow hits the peripheral portion, resulting in that the drying of the coating film becomes excessive. The prevention of the excessive drying of the coating film is also one of reasons why the gas flow guide 80 is provided.

The explanation is returned to the thermal treatment sequence.

When a predetermined time elapses after the wafer W is mounted on the hot plate 30 and the heating of the wafer W, namely, the drying of the coating film on the wafer W is completed, the raising and lowering pins 33 are raised, whereby the wafer W is supported by the raising and lowering pins 33 and separated from the hot plate 30, and the heating of the wafer W by the hot plate 30 is finished. Further, the exhaust of gas by the exhauster 50 is stopped.

Next, the shutter 70 is raised up to the carry position, the opening 40a is brought into the fully open state, and the cooling plate 20 is inserted between the hot plate 30 and the wafer W supported by the raising and lowering pins 33. Subsequently, the raising and lowering pins 33 are lowered, whereby the wafer W is delivered to the cooling plate 20. Subsequently, the cooling plate 20 on which the wafer W is mounted is moved to the temperature regulation region 14. The wafer W is then cooled by the cooling plate 20 for a predetermined time and thereby temperature-regulated.

Thereafter, the raising and lowering pins 22 are raised, whereby the wafer W is supported by the raising and lowering pins 22 and separated from the cooling plate 20. Next, the exhaust of gas from the space S2 via the exhaust port 27b is stopped. In addition, the carry-in/out port 10a is brought into the open state by the opening and closing shutter 10b, and the wafer carrier apparatus (not illustrated) is inserted between the cooling plate 20 and the wafer W supported by the raising and lowering pins 22, through the carry-in/out port 10a. Then, the raising and lowering pins 22 are lowered, whereby the wafer W is supported on the wafer carrier apparatus. The wafer W is then carried out of the housing 10 by the wafer carrier apparatus.

This completes the serial thermal treatment sequence.

### Main Effects of This Embodiment

As explained above, according to the thermal treatment apparatus 1, it is possible to prevent the drying of the coating film from becoming excessive at the peripheral portion on the opening 40a side of the wafer W on the hot plate 30. It is also possible to prevent the concentration of a vaporized solvent from becoming high around the portion on the exhauster 50 side of the wafer W and the solvent from becoming difficult to vaporize from the coating film. In other words, according to the thermal treatment apparatus 1, it is possible to improve the in-plane uniformity of the result of the heat treatment which dries the coating film. Although not limiting the usage, the thermal treatment apparatus 1 can perform a heat treatment uniform within a plane, in particular, regarding the coating film of the resist solution exemplified in the above.

Further, as explained above, the gas flow guide 80 is provided so that, for example, the interval L1 between the gas flow guide 80 and the ceiling surface being the surface on the treatment space S1 side and the lower side of the upper cover 40 (namely, the lower surface of the ceiling part 41) is larger than the interval L2 between the shutter 70 and the gas flow guide 80. The provision of the gas flow guide 80 as above reduces the pressure loss in the gap between the lower surface of the ceiling part 41 and the gas flow guide 80 and thereby can strengthen the gas flow flowing through the gap and weaken the gas flow proceeding downward via the gap G between the shutter 70 and the gas flow guide 80.

Further, in this embodiment, the width (length in the Y-direction in the drawing) of the gas flow guide 80 is the width where the end on the hot plate 30 side (Y-direction positive side in the drawing) of the gas flow guide 80 does not overlap with the wafer W mounted on the hot plate 30 in top view as explained above. Therefore, the pressure loss in the gap between the lower surface of the ceiling part 41 and the gas flow guide 80 can be made smaller than that in the case where the end on the hot plate 30 side (Y-direction positive side in the drawing) of the gas flow guide 80 overlaps with the wafer W mounted on the hot plate 30 in top view. Therefore, it is possible to strengthen the gas flow flowing through the gap and weaken the gas flow proceeding downward via the gap G between the shutter 70 and the gas flow guide 80.

Further, in this embodiment, the peripheral cover 44 which covers the gap at the lateral side of the hot plate 30 from above and extends to above the peripheral portion of the hot plate 30 is provided as explained above. Therefore, it is possible to prevent the peripheral portion of the wafer W on the hot plate 30 from being cooled by the gas flow passing through the gap at the lateral side of the hot plate 30.

Further, in this embodiment, the position of the upper surface of the peripheral cover 44 (specifically, the upper surface of the annular part 45) is higher than the position of the front surface of the wafer W mounted on the hot plate 30 as explained above. Therefore, it is possible to prevent the gas flow which proceeds downward via the gap G between the gas flow guide 80 and the shutter 70 and then proceeds along the upper surface of the peripheral cover 44 toward the wafer W on the hot plate 30, from hitting the wafer W.

Further, in this embodiment, the gas flow guide 80 is attached to the lower surface of the ceiling part 41 by being connected thereto at not only both the end portions but also at least the central portion in the predetermined direction. Therefore, the gas flow guide 80 can be more efficiently heated via the ceiling part 41 provided with the heater 43 than in the case where only both the end portions of the gas flow guide 80 are connected to the lower surface of the ceiling part 41. Therefore, it is possible to prevent the solvent vaporized from the coating film on the wafer W from condensing at the gas flow guide 80.

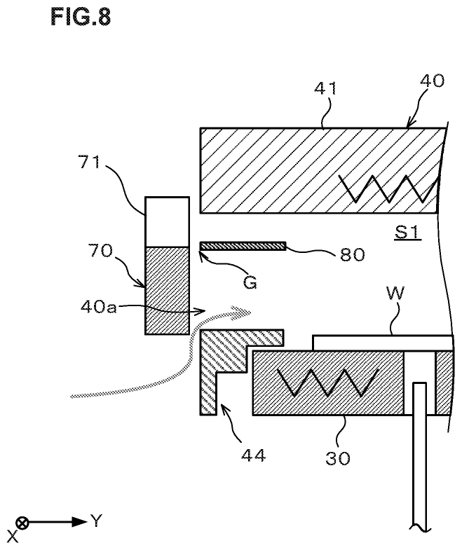

Further, in this embodiment, the base wall 27 and the exhaust port 27b are provided. In the case where the base wall 27 and the exhaust port 27b are not provided, gas flows from a gap GL between the lower portion of the shutter 70 and the peripheral cover 44 as indicated by a gray arrow in FIG. 8 and flows into the treatment space S1, namely, the gas flow enters the treatment space S1 via the gap GL and the lower portion of the opening 40a. This gas flow hits the peripheral portion on the opening 40a side of the wafer W on the hot plate 30 and thus affects the drying of the coating film at the peripheral portion. In contrast to the above, the provision of the base wall 27 and the exhaust port 27b forms the gas flow proceeding toward the exhaust port 27b, thereby making it difficult to form a gas flow entering the treatment space S1 via the gap GL and the lower portion of the opening 40a. Therefore, it is possible to prevent the drying of the coating film at the peripheral portion from being affected by the gas flow entering the treatment space S1 via the gap GL and the lower portion of the opening 40a.

Further, the provision of the base wall 27 and the exhaust port 27b makes it possible to more surely form the gas flow as explained using FIG. 7.

### Another Example of the Thermal Treatment Sequence

In the above example, when the wafer W is carried into the treatment space S1 and then the lowering of the shutter 70 down to the treatment position, namely, the transition of the shutter 70 to the closed state is completed, the raising and lowering pins 33 are lowered immediately thereafter to mount the wafer W on the hot plate 30.

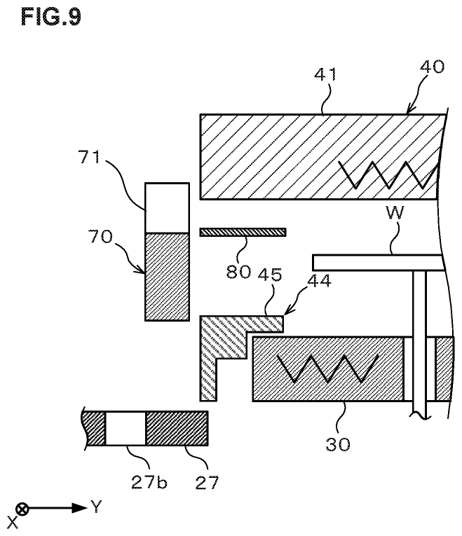

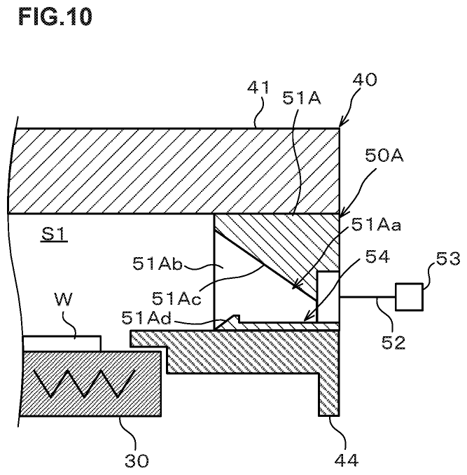

Instead of the above, in this example, after the wafer W is carried into the treatment space S1 and before the wafer W is mounted on the hot plate 30, pre-drying of bringing the shutter 70 into a closed state and keeping the wafer W separated from the hot plate 30 by a predetermined distance is performed as illustrated in FIG. 9. More specifically, in this example, after the wafer W is carried into the treatment space S1 and before a main drying of heating the wafer W mounted on the hot plate 30 by the hot plate 30, the pre-drying is performed. The volatilization amount per unit time, namely, volatilization rate, of the solvent in the coating film on the hot plate 30 is high in the main drying and low in the pre-drying.

As in this example, by performing the pre-drying low in the volatilization rate before the main drying high in volatilization rate, it is possible to suppress the volatilization amount of the solvent in the coating film on the hot plate 30 in the main drying high in volatilization rate. This can prevent the volatilization amount of the solvent from varying within the plane of the wafer W. In other words, it is possible to prevent the occurrence of unevenness in drying of the solvent within the plane of the wafer W.

Note that the position, namely, the height of the wafer W during the pre-drying may be substantially the same as that of the gas flow guide 80.

### Another Example of the Exhauster

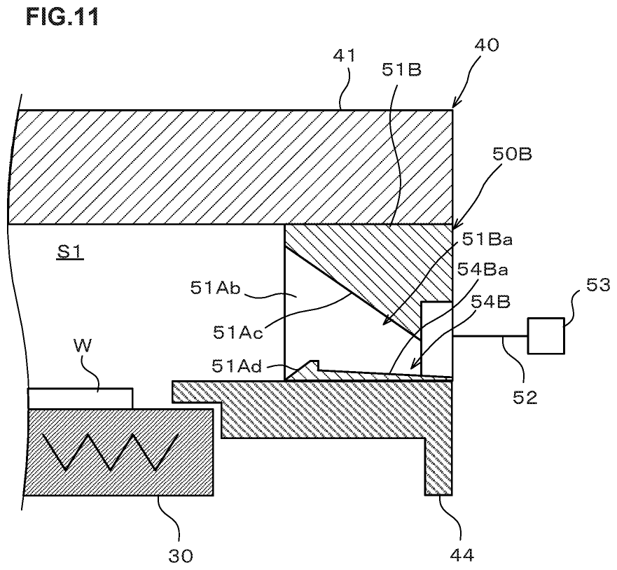

FIG. 10 and FIG. 11 are views explaining another example of the exhauster, respectively.

As with the exhauster 50 illustrated in FIG. 2 and so on, an exhauster 50A in FIG. 10 has a forming member 51A which forms an exhaust flow path 51Aa communicating with the treatment space S1, and the exhaust flow path 51Aa includes an exhaust port 51Ab opening to the treatment space S1.

However, unlike the exhauster 50, the exhauster 50A has a surface 51Ac on the exhaust flow path 51Aa side at the upper portion of the forming member 51A, which is an inclined surface (hereinafter, referred to as a “downward inclined surface”) inclined downward from the exhaust upstream side to the exhaust downstream side. In this example, the surface 51Ac forms (a part of) the exhaust port 51Ab.

By forming the surface 51Ac into the downward inclined surface, even if the solvent vaporizing from the coating film on the wafer W condenses on the surface 51Ac, the condensed solvent flows along the inclined surface to the exhaust downstream side. Therefore, the condensed solvent can be easily put together to be drained.

Further, the exhauster 50A has, below the surface 51Ac, a liquid receiver 54 which receives liquid, namely, the solvent condensed on the surface 51Ac being the downward inclined surface and dropping from the surface 51Ac. The solvent in the liquid receiver 54 is drained from the opposite side to the hot plate 30, for example, via the exhaust pipe 52 which also serves as the drain pipe.

The end portion on the hot plate 30 side of the liquid receiver 54 may be formed higher than the other portion. This can prevent the solvent in the liquid receiver 54 from proceeding toward the hot plate 30.

Further, an end surface 51Ad on the hot plate 30 side at the lower portion of the forming member 51A of the exhauster 50A is an inclined surface (hereinafter, referred to as an “upward inclined surface”) inclined upward from the exhaust upstream side to the exhaust downstream side. Specifically, an upper portion of the end surface 51Ad on the hot plate 30 side at the end portion on the hot plate 30 side of the liquid receiver 54 is the upward inclined surface.

This makes the gas flow containing the solvent vaporized from the coating film smoothly flow into the forming member 51A and thereby can prevent the gas flow from staying in the forming member 51A to cause condensation. Specifically, it is possible to prevent the gas flow containing the solvent from staying on the side opposite to the hot plate 30 side at the end portion on the hot plate 30 side of the liquid receiver 54.

Besides, as in an exhauster 50B in FIG. 11, a bottom surface 54Ba of a liquid receiver 54B of a forming member 51B which forms an exhaust flow path 51Ba may be a downward inclined surface.

This can facilitate the flow of the solvent received by the liquid receiver 54B to the exhaust downstream side (namely, toward the exhaust pipe 52 also serving as the drain pipe).

### Another Example of the Peripheral Cover

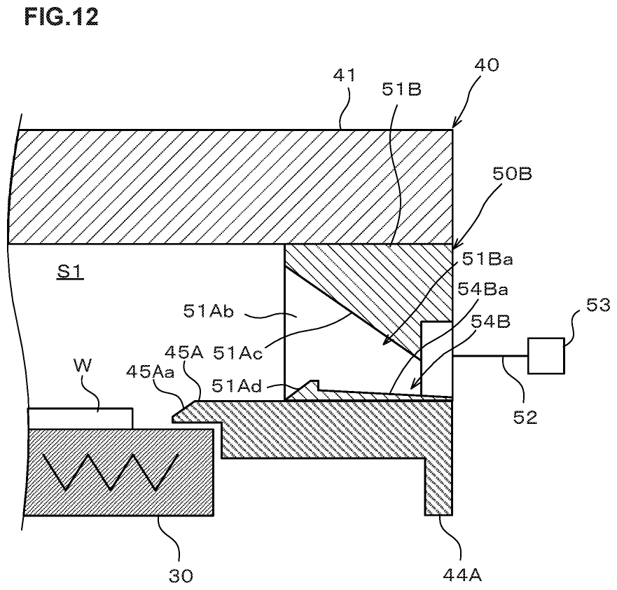

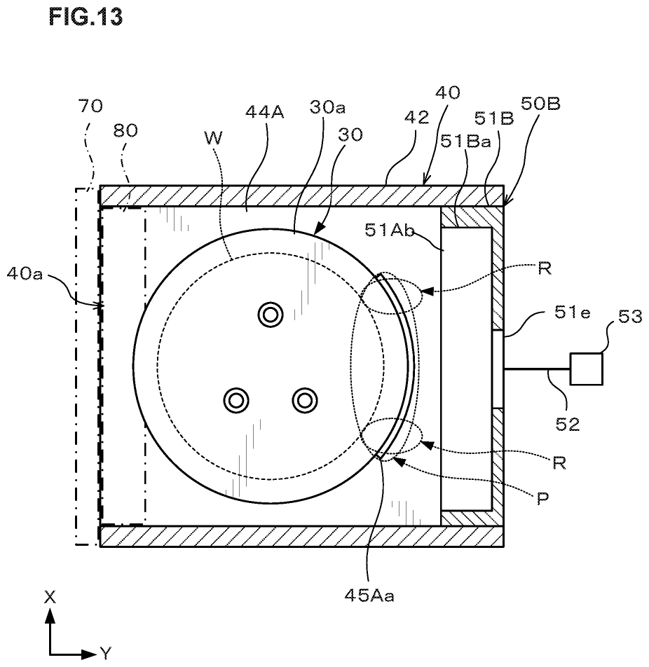

FIG. 12 is a view explaining another example of the peripheral cover. FIG. 13 is a view explaining a formation region of an inclined surface at the peripheral cover in FIG. 12.

An inner peripheral side end surface 45Aa of an annular part 45A of a peripheral cover 44A in FIG. 12 is an inclined surface inclined upward toward the outer side. Specifically, an upper part of the inner peripheral side end surface 45Aa of the annular part 45A of the peripheral cover 44A is the above-explained inclined surface. In other words, an upper side corner portion at the inner peripheral side end of the peripheral cover 44A is composed of an inclined surface. Further, as illustrated in FIG. 13, a portion (hereinafter, referred to as an “inclination processed portion”) P where the inner peripheral side end surface 45Aa is formed as the above-explained inclined surface in the peripheral cover 44A is only on the exhauster 50B side.

By forming the inner peripheral side end surface 45Aa as above, the gas flow containing the solvent vaporized from the coating film smoothly flows along the upper surface of the peripheral cover 44A toward the exhauster 50B. In other words, it is possible to prevent the gas flow containing the solvent vaporized from the coating film from staying directly above the inner peripheral side end portion of the annular part 45A of the peripheral cover 44A. Accordingly, it is possible to prevent the condensation from occurring on the inner peripheral side end portion of the annular part 45A of the peripheral cover 44A.

A length of the inclination processed portion P of the peripheral cover 44A in a predetermined direction being a direction in which the opening 40a extends and which crosses the vertical direction, namely, the X-direction in the drawing is, for example, equal to or larger than the length of the exhaust flow path 51Ba at the exhaust downstream side end, namely, the outlet port 51e. However, when the length of the outlet port 51e in the X-direction is less than the radius of the wafer W, the length of the inclination processed portion P in the X-direction is equal to or larger than the radius of the wafer W. Further, the length of the inclination processed portion P in the X-direction is equal to or less than the length of the exhaust flow path 51Ba at the exhaust downstream side end, namely, the exhaust port 51Ab. However, when the length of the exhaust port 51Ab in the X-direction is equal to or less than the length of the notch 71 of the shutter 70, the length of the inclination processed portion P is equal to or less than the length of the notch 71 of the shutter 70.

Keeping the length of the inclination processed portion P of the peripheral cover 44 in the X-direction within the above range brings about the following effect.

On the exhauster 50B side of the peripheral cover 44A, the gas flow is fast in a region R between the side end of the exhaust port 51Ab and the outlet port 51e (specifically, a middle region between them) in Y-direction view in the drawing. If the length of the inclination processed portion P in the X-direction falls within the above range, the gas flow can be made to smoothly flow along the upper surface of the peripheral cover 44A also in this region R where the gas flow is fast.

The embodiments disclosed herein are examples in all respects and should not be considered to be restrictive. Various omissions, substitutions, and changes may be made in the embodiments without departing from the scope and spirit of the attached claims. For example, configuration requirements of the above embodiments can be arbitrarily combined. The operations and effects about the configuration requirements relating to an arbitrary combination can be obtained as a matter of course from the combination, and those skilled in the art can obtain clear other operations and other effects from the description herein.

Further, the effects explained herein are merely explanatory or illustrative in all respects and not restrictive. The technique relating to this disclosure can offer other clear effects to those skilled in the art from the description herein in addition to or in place of the above effects.

Note that the following configuration examples also belong to the technical scope of this disclosure.
(1) A thermal treatment apparatus for performing a heat treatment on a substrate, the thermal treatment apparatus including:
   a hot plate on which the substrate is mounted and which is configured to heat the mounted substrate;
   an upper cover configured to cover a treatment space above the hot plate and form an opening being a carry-in/out port for the substrate to/from the treatment space;
   an exhauster provided at a position opposite to the opening across the hot plate in plan view and configured to exhaust gas from the treatment space;
   a shutter configured to be able to cover a lower portion of the opening; and
   a gas flow guide provided at a position spaced apart from the shutter, wherein
   the gas flow guide divides gas flowing into the treatment space due to the exhaust of gas by the exhauster from an upper portion of the opening whose lower portion is covered with the shutter, into an upper side and a lower side.
(2) The thermal treatment apparatus according to the (1), wherein
   an interval between the gas flow guide and a ceiling surface being a surface on the treatment space side and a lower side of the upper cover is larger than an interval between the shutter and the gas flow guide.
(3) The thermal treatment apparatus according to the (1) or (2), further including
   an exhaust port configured to exhaust gas from another space opposite to the treatment space across the shutter, from below the shutter.
(4) The thermal treatment apparatus according to any one of the (1) to (3), further including
   a heater configured to heat a ceiling surface being a surface on the treatment space side and a lower side of the upper cover, separately from the hot plate, wherein
   the gas flow guide is:
   provided along a predetermined direction being a direction in which the opening extends and which crosses a vertical direction; and
   connected, at a central portion and both end portions in the predetermined direction, to the ceiling surface.
(5) The thermal treatment apparatus according to any one of the (1) to (4), further including
   a peripheral cover configured to cover a gap at a lateral side of the hot plate from above and extending to above a peripheral portion of the hot plate.
(6) The thermal treatment apparatus according to the (5), wherein
   an inner peripheral side end surface of the peripheral cover is, at least on the exhauster side, an inclined surface inclined upward toward an outer side.
(7) The thermal treatment apparatus according to the (6), wherein
   the exhauster has a forming member which forms an exhaust flow path communicating with the treatment space; and
   a length, of a portion on the exhauster side of the peripheral cover where the inner peripheral side end surface is the inclined surface, in a predetermined direction being a direction in which the opening extends and which crosses a vertical direction is equal to or larger than a length, of the exhaust flow path at an exhaust downstream side end, in the predetermined direction.
(8) The thermal treatment apparatus according to any one of the (1) to (7), wherein
   the exhauster has a forming member which forms an exhaust flow path communicating with the treatment space; and
   a surface on the exhaust flow path side at an upper portion of the forming member is an inclined surface inclined downward from an exhaust upstream side to an exhaust downstream side.
(9) The thermal treatment apparatus according to the (8), wherein
   the exhauster has, below the inclined surface, a liquid receiver configured to receive liquid condensed on the inclined surface.
(10) The thermal treatment apparatus according to the (8) or (9), wherein
   an end surface on the hot plate side at a lower portion of the forming member of the exhauster is an inclined surface inclined upward from the exhaust upstream side to the exhaust downstream side.
(11) The thermal treatment apparatus according to the (9) or (10), wherein
a bottom surface of the liquid receiver is an inclined surface inclined downward from the exhaust upstream side to the exhaust downstream side.
(12) The thermal treatment apparatus according to any one of the (1) to (11), further including
a raising and lowering member configured to raise and lower the substrate with respect to the hot plate; and
a controller, wherein
the controller performs control to perform a pre-drying of bringing the shutter into a closed state and keeping the substrate separated from the hot plate by a predetermined distance, after the substrate is carried into the treatment space and before the substrate is mounted on the hot plate.
(13) A thermal treatment method of performing a heat treatment on a substrate using a thermal treatment apparatus,
   the thermal treatment apparatus including:
      a hot plate on which the substrate is mounted and which is configured to heat the mounted substrate;
      an upper cover configured to cover a treatment space above the hot plate and form an opening being a carry-in/out port for the substrate to/from the treatment space; and
      an exhauster provided at a position opposite to the opening across the hot plate in plan view and configured to exhaust gas from the treatment space,
   the thermal treatment method including heating the substrate in the treatment space while exhausting gas by the exhauster, wherein
   in the heating,
      a shutter for the opening is brought into a closed state and a lower portion of the opening is covered with the shutter, and
      gas flowing into the treatment space from an upper portion of the opening due to the exhaust of gas by the exhauster is divided into an upper side and a lower side by a gas flow guide provided at a position spaced apart from the shutter.
(14) The thermal treatment method according to the (13), wherein
   in the heating, pre-drying of bringing the shutter into a closed state and keeping the substrate separated from the hot plate by a predetermined distance is performed after the substrate is carried into the treatment space and before the substrate is mounted on the hot plate.

According to this disclosure, it is possible to improve the in-plane uniformity of the result of a heat treatment in the case of performing the heat treatment on a substrate in a treatment space in a state where a gas flow formed by a carry-in/out port for the substrate and an exhauster opposite to each other across a hot plate in plan view is formed in a treatment space above the hot plate.

What is claimed is:

1. A thermal treatment apparatus for performing a heat treatment on a substrate, the thermal treatment apparatus comprising:
a hot plate on which the substrate is mounted and which is configured to heat the mounted substrate;
an upper cover configured to cover a treatment space above the hot plate and form an opening being a carry-in/out port for the substrate to/from the treatment space;
an exhauster provided at a position opposite to the opening across the hot plate in plan view and configured to exhaust gas from the treatment space;
a shutter configured to be able to cover a lower portion of the opening; and
a gas flow guide provided at a position spaced apart from the shutter, wherein
the gas flow guide divides gas flowing into the treatment space due to the exhaust of gas by the exhauster from an upper portion of the opening whose lower portion is covered with the shutter, into an upper side and a lower side.

2. The thermal treatment apparatus according to claim 1, wherein
an interval between the gas flow guide and a ceiling surface being a surface on the treatment space side and a lower side of the upper cover is larger than an interval between the shutter and the gas flow guide.

3. The thermal treatment apparatus according to claim 1, further comprising
an exhaust port configured to exhaust gas from another space opposite to the treatment space across the shutter, from below the shutter.

4. The thermal treatment apparatus according to claim 1, further comprising
a heater configured to heat a ceiling surface being a surface on the treatment space side and a lower side of the upper cover, separately from the hot plate, wherein
the gas flow guide is:
provided along a predetermined direction being a direction in which the opening extends and which crosses a vertical direction; and
connected, at a central portion and both end portions in the predetermined direction, to the ceiling surface.

5. The thermal treatment apparatus according to claim 1, further comprising
a peripheral cover configured to cover a gap at a lateral side of the hot plate from above and extending to above a peripheral portion of the hot plate.

6. The thermal treatment apparatus according to claim 5, wherein
an inner peripheral side end surface of the peripheral cover is, at least on the exhauster side, an inclined surface inclined upward toward an outer side.

7. The thermal treatment apparatus according to claim 6, wherein:
the exhauster has a forming member which forms an exhaust flow path communicating with the treatment space; and
a length, of a portion on the exhauster side of the peripheral cover where the inner peripheral side end surface is the inclined surface, in a predetermined direction being a direction in which the opening extends and which crosses a vertical direction is equal to or larger than a length, of the exhaust flow path at an exhaust downstream side end, in the predetermined direction.

8. The thermal treatment apparatus according to claim 1, wherein:
the exhauster has a forming member which forms an exhaust flow path communicating with the treatment space; and
a surface on the exhaust flow path side at an upper portion of the forming member is an inclined surface inclined downward from an exhaust upstream side to an exhaust downstream side.

9. The thermal treatment apparatus according to claim 8, wherein
the exhauster has, below the inclined surface, a liquid receiver configured to receive liquid condensed on the inclined surface.

10. The thermal treatment apparatus according to claim 9, wherein
an end surface on the hot plate side at a lower portion of the forming member of the exhauster is an inclined surface inclined upward from the exhaust upstream side to the exhaust downstream side.

11. The thermal treatment apparatus according to claim 9, wherein
a bottom surface of the liquid receiver is an inclined surface inclined downward from the exhaust upstream side to the exhaust downstream side.

12. The thermal treatment apparatus according to claim 1, further comprising:
a raising and lowering member configured to raise and lower the substrate with respect to the hot plate; and
a controller, wherein
the controller performs control to perform a pre-drying of bringing the shutter into a closed state and keeping the substrate separated from the hot plate by a predetermined distance, after the substrate is carried into the treatment space and before the substrate is mounted on the hot plate.

13. A thermal treatment method of performing a heat treatment on a substrate using a thermal treatment apparatus,
the thermal treatment apparatus comprising:
a hot plate on which the substrate is mounted and which is configured to heat the mounted substrate;
an upper cover configured to cover a treatment space above the hot plate and form an opening being a carry-in/out port for the substrate to/from the treatment space; and
an exhauster provided at a position opposite to the opening across the hot plate in plan view and configured to exhaust gas from the treatment space,
the thermal treatment method comprising heating the substrate in the treatment space while exhausting gas by the exhauster, wherein
in the heating,
a shutter for the opening is brought into a closed state and a lower portion of the opening is covered with the shutter, and
gas flowing into the treatment space from an upper portion of the opening due to the exhaust of gas by the exhauster is divided into an upper side and a lower side by a gas flow guide provided at a position spaced apart from the shutter.

14. The thermal treatment method according to claim 13, wherein
in the heating, pre-drying of bringing the shutter into a closed state and keeping the substrate separated from the hot plate by a predetermined distance is performed after the substrate is carried into the treatment space and before the substrate is mounted on the hot plate.
